(19) United States
(12) Patent Application Publication
(10) Pub. No.: US 2013/0206463 A1
(43) Pub. Date: Aug. 15, 2013

(54) NON-HALOGENATED FLAME RETARDANT FILLER

(71) Applicants: Dylan J. Boday, Tucson, AZ (US); Joseph Kuczynski, Rochester, MN (US); Robert E. Meyer, III, Rochester, MN (US)

(72) Inventors: Dylan J. Boday, Tucson, AZ (US); Joseph Kuczynski, Rochester, MN (US); Robert E. Meyer, III, Rochester, MN (US)

(73) Assignee: INTERNATIONAL BUSINESS MACHINES CORPORATION, Armonk, NY (US)

(21) Appl. No.: 13/397,010

(22) Filed: Feb. 15, 2012

(51) Int. Cl. H05K 1/02; C07F 9/40; B32B 1/06; C08K 5/5333

(52) U.S. Cl. 174/258; 428/36.4; 556/404

(57) ABSTRACT

A non-halogenated flame retardant filler having phosphorous-modified inorganic particles imparts flame retardancy to manufactured articles such as printed circuit boards (PCBs), connectors, and other articles of manufacture that employ thermosetting plastics or thermoplastics. Phosphorous-modified silica particles, for example, may serve both as a filler for rheology control (viscosity, flow, etc.) and a flame retardant. In an exemplary application, a PCB laminate stack-up includes conductive planes separated from each other by a dielectric material that includes a non-halogenated flame retardant filler comprised of phosphorous-modified silica particles. In an exemplary method of synthesizing phosphorous-modified silica particles, a vinyl-terminated phosphorous-based monomer (e.g., a phosphorous based flame retardant functionalized to contain a vinyl functional group) is reacted with vinyl functionalized silica particles (i.e., the silica particle surface is functionalized to contain a vinyl functional group). Alternatively, hydrosilated terminated silica particles may be reacted with a vinyl-terminated phosphorous-based monomer to produce phosphorous-modified silica particles.

### BACKGROUND OF THE INVENTION

1. Field of Invention

The present invention relates in general to the field of flame retardancy. More particularly, the present invention relates to using a non-halogenated flame retardant filler to impart flame retardancy to manufactured articles such as printed circuit boards (PCBs), connectors, and other articles of manufacture that employ thermosetting plastics or thermoplastics.

2. Background Art

In the manufacture of PCBs, connectors, and other articles of manufacture that employ thermosetting plastics (also known as “thermosets”) or thermoplastics, incorporation of a filler material as well as a flame retardant is required for rheology control (viscosity, flow, etc.) and ignition resistance, respectively. Typically, both attributes are not found in one material. That is, silica particles are generally the filler of choice for rheology control, whereas brominated organic compounds impart flame retardancy. Consequently, the base material (e.g., epoxy resin for PCBs, and liquid crystal polymer (LCP) for connectors) properties are compromised because a relatively large quantity of both a filler and a flame retardant is necessary to achieve the desired properties.

Therefore, a need exists for an improved mechanism for imparting flame retardancy to manufactured articles such as PCBs, connectors, and other articles of manufacture that employ thermoplastics or thermosets.

### SUMMARY OF THE INVENTION

In accordance with some embodiments of the present invention, a non-halogenated flame retardant filler having phosphorous-modified inorganic particles imparts flame retardancy to manufactured articles such as printed circuit boards (PCBs), connectors, and other articles of manufacture that employ thermosetting plastics or thermoplastics. Phosphorous-modified silica particles, for example, may serve both as a filler for rheology control (viscosity, flow, etc.) and a flame retardant. In an exemplary application, a PCB laminate stack-up includes conductive planes separated from each other by a dielectric material that includes a non-halogenated flame retardant filler comprised of phosphorous-modified silica particles. In an exemplary method of synthesizing phosphorous-modified silica particles, a vinyl-terminated phosphorous-based monomer (e.g., a phosphorous based flame retardant functionalized to contain a vinyl functional group) is reacted with vinyl functionalized silica particles (i.e., the silica particle surface is functionalized to contain a vinyl functional group). Alternatively, hydrosilated terminated silica particles may be reacted with a vinyl-terminated phosphorous-based monomer to produce phosphorous-modified silica particles.

### BRIEF DESCRIPTION OF THE DRAWINGS

The preferred exemplary embodiments of the present invention will hereinafter be described in conjunction with the appended drawings, where like designations denote like elements.

FIG. 1 is a block diagram illustrating an exemplary printed circuit board (PCB) having layers of dielectric material that incorporate a non-halogenated flame retardant filler having phosphorous-modified inorganic particles in accordance with some embodiments of the present invention.

FIG. 2 is a block diagram illustrating an exemplary laminate stack-up of the PCB shown in FIG. 1.

FIG. 3 is a block diagram illustrating an exemplary connector having a plastic housing that incorporates a non-halogenated flame retardant filler having phosphorous-modified inorganic particles in accordance with some embodiments of the present invention.

### DETAILED DESCRIPTION OF THE PREFERRED EMBODIMENTS

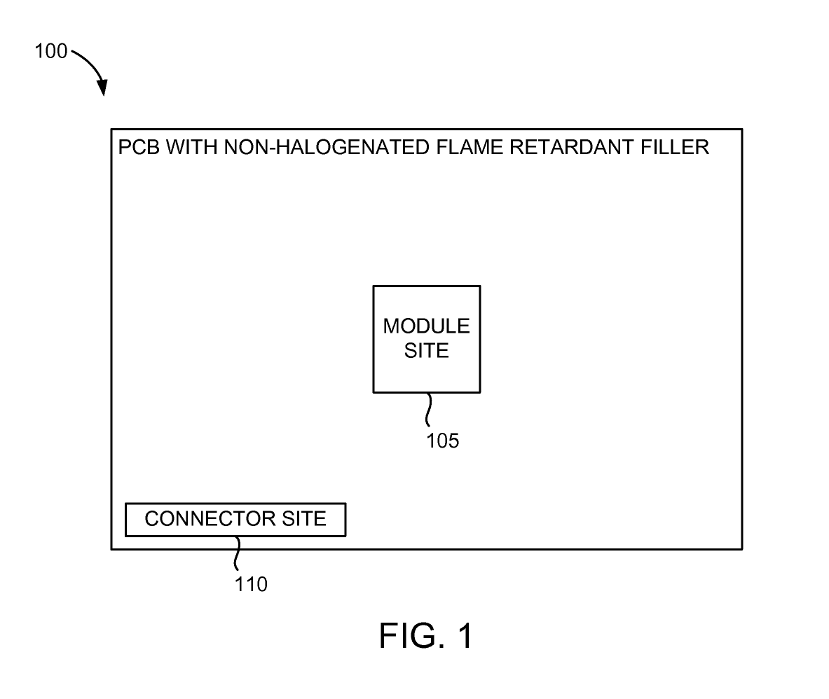

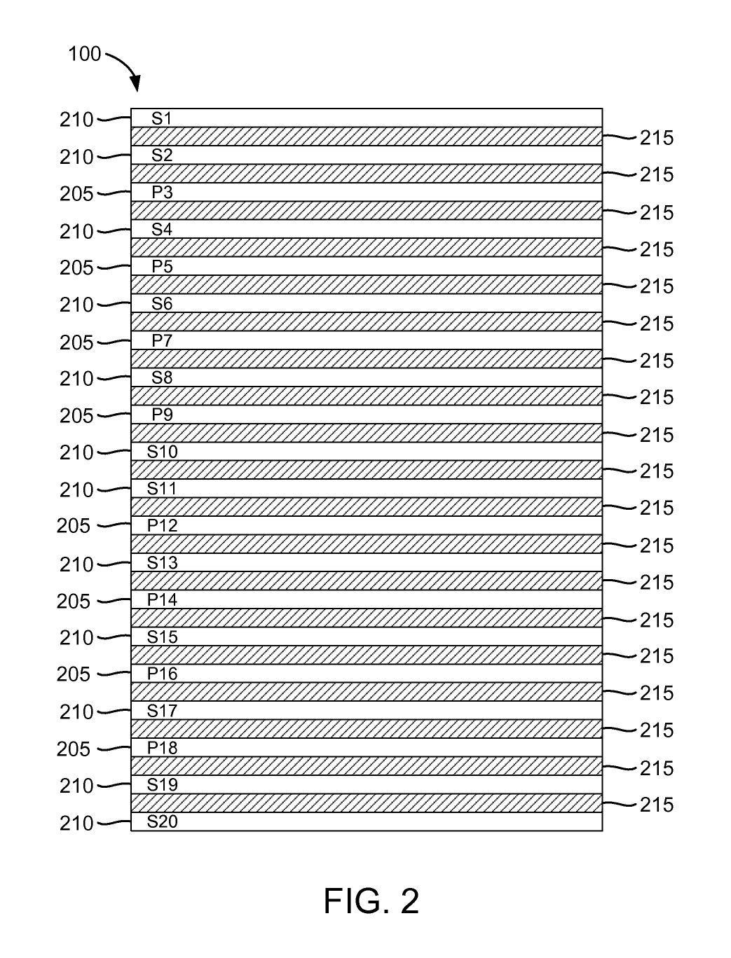

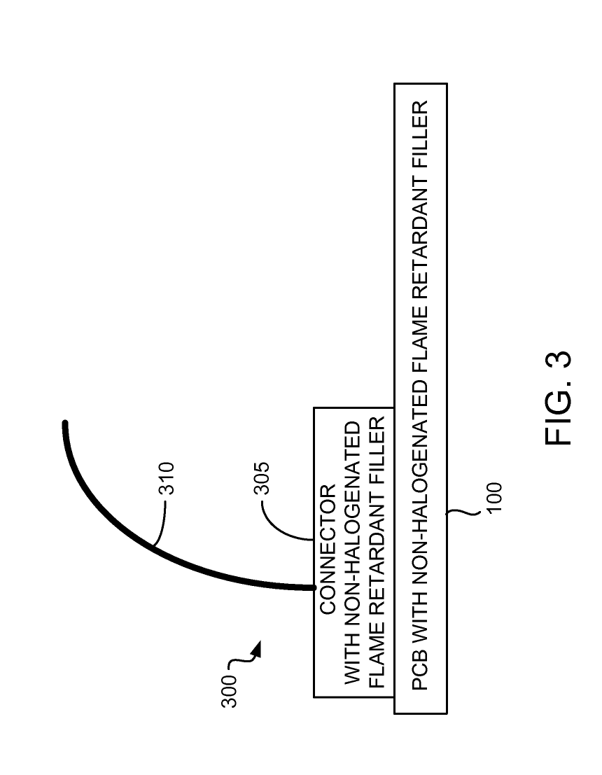

In accordance with some embodiments of the present invention, a non-halogenated flame retardant filler having phosphorous-modified inorganic particles imparts flame retardancy to manufactured articles such as printed circuit boards (PCBs), connectors, and other articles of manufacture that employ thermosetting plastics or thermoplastics. Phosphorous-modified silica particles, for example, may serve both as a filler for rheology control (viscosity, flow, etc.) and a flame retardant. An exemplary printed circuit board (PCB) implementation of the present invention is described below with reference to FIGS. 1 and 2, while an exemplary connector implementation of the present invention is described below with reference to FIG. 3. However, those skilled in the art will appreciate that the present invention applies equally to any manufactured article that employs thermosetting plastics (also known as “thermosets”) or thermoplastics.

As described below, phosphorous-modified silica particles in accordance with some embodiments of the present invention may be synthesized by, for example, reacting a vinyl-terminated phosphorous-based monomer (e.g., a phosphorous based flame retardant, such as dimethyl propyl phosphonate, functionalized to contain a vinyl functional group) and vinyl functionalized silica particles (e.g., the silica particle surface is functionalized to contain a functional group). This first pathway to prepare phosphorous-modified silica particles in accordance with some embodiments of the present invention is exemplified by reaction scheme 1, below. However, those skilled in the art will appreciate that phosphorous-modified silica particles in accordance with some embodiments of present invention may be synthesized using other processes and reaction schemes. For example, hydrosilated terminated silica particles may be reacted with an appropriate vinyl-terminated phosphorous-based monomer (e.g., a phosphorous based flame retardant, such as dimethyl propyl phosphonate, functionalized to contain a vinyl functional group) to produce phosphorous-modified silica particles. This second pathway to prepare phosphorous-modified silica particles in accordance with some embodiments of the present invention is exemplified by reaction scheme 2, below.

Those skilled in the art will appreciate that in addition to being applicable to preparing phosphorous-modified silica particles, the first and second pathways are, more generally, applicable to preparing inorganic particles of any type (e.g., silica, talc, mica, kaolin, clay, aluminum hydroxide, aluminum silicate, titanium dioxide, metals such as aluminum and indium, alumina, glass beads, and the like) modified to incorporate phosphorous-based species. In accordance with some embodiments of the present invention, suitable inorganic particles must have surface hydroxyl groups (i.e., hydroxyl groups on the surface of the inorganic particle). In accordance with some embodiments of the present invention, a silane coupling agent reacts with these hydroxyl groups to form either vinyl-modified inorganic particles (e.g., the first step in reaction scheme 1, below) or hydrosilated terminated inorganic particles (e.g., the first step in reaction scheme 2, below), which are subsequently modified to incorporate phosphorous-based species. In its most general term, this reaction involves condensation of the trialkoxy silane with surface hydroxyls to form Si—O-substrate bonds. If the surface hydroxyls are not present, the condensation reaction cannot ensue. In terms of size, the inorganic particles may be course particles, fine particles, ultrafine particles, or nanoparticles.

In addition, those skilled in the art will appreciate that in the first pathway, other types of functionalized inorganic particles (e.g., the silica and/or other inorganic particle surface functionalized to contain a suitable functional group) may be reacted with any suitably functionalized phosphorous-based monomer (e.g., a phosphorous based flame retardant functionalized to contain a suitable functional group). Similarly, those skilled in the art will appreciate that in the second pathway, hydrosilated terminated silica particles may be reacted with any suitably functionalized phosphorous-based monomer (e.g., a phosphorous based flame retardant functionalized to contain a suitable functional group). In general, suitable functional groups may include vinyl, isocyanate, amine, and epoxy functional groups.

Functionalized inorganic particles (e.g., vinyl functionalized silica particles) and hydrosilated terminated inorganic particles (e.g., hydrosilated terminated silica particles) from which phosphorous-modified inorganic particles in accordance with some embodiments of the present invention are produced, may be either obtained commercially or synthesized. Vinyl functionalized silica particles, for example, are either commercially available or can be readily prepared by reacting a commercially available silane coupling agent (e.g., vinyltriethoxysilane) with a silica particle. Hydrosilated terminated silica particles, for example, are either commercially available or can be readily prepared by reacting a commercially available silane coupling agent (e.g., triethoxysilane) with a silica particle.

Functionalized phosphorous-based monomers suitable for reacting with functionalized inorganic particles and/or hydrosilated terminated inorganic particles to produce phosphorous-modified inorganic particles in accordance with some embodiments of the present invention may be either obtained commercially or synthesized. For example, suitable functionalized phosphorous-based monomers that may be obtained commercially include dimethyl vinylphosphonate, dimethyl allylphosphonate, diethyl vinylphosphonate, and diethyl allylphosphonate. Generally, suitable functionalized phosphorous-based monomers may be synthesized by functionalizing a conventional phosphorous-based flame retardant, such as a phosphonate (e.g., dimethyl methyl phosphonate; diethyl ethyl phosphonate; dimethyl propyl phosphonate; diethyl N,N-bis(2-hydroxyethyl) amino methyl phosphonate; phosphonic acid, methyl(5-methyl-2-methyl-1,3,2-dioxaphosphorinan-5-y) ester, P,P′-dioxide; and phosphonic acid, methyl(5-methyl-2-methyl-1,3,2-dioxaphosphorinan-5-yl) methyl, methyl ester, P-oxide), a phosphate ester (e.g., triethyl phosphate; tributyl phosphate; trioctyl phosphate; and tributoxyethyl phosphate), or a phosphinate.

A conventional phosphorous-based flame retardant typically includes one or more of a phosphonate, a phosphate ester, or a phosphinate. Conventional phosphorous-based flame retardants that are phosphonates have the following generic molecular structure:

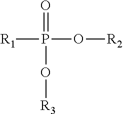

where R₁, R₂ and R₃ are organic substituents (e.g., alkyl, aryl, etc.) that may be the same or different.

Conventional phosphorous-based flame retardants that are phosphate esters have the following generic molecular structure:

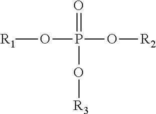

where R₁, R₂ and R₃ are organic substituents (e.g., alkyl, aryl, etc.) that may be the same or different.

Conventional phosphorous-based flame retardants that are phosphinates have the following generic molecular structure:

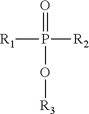

where R₁, R₂ and R₃ are organic substituents (e.g., alkyl, aryl, etc.) that may be the same or different.

One or more of the above conventional phosphorous-based flame retardants (i.e., phosphonate, phosphate ester, and/or phosphinate) and/or other conventional phosphate-based flame retardants may be functionalized using procedures well known to those skilled in the art to produce functionalized phosphorous-based monomers suitable for reacting with functionalized inorganic particles and/or hydrosilated terminated inorganic particles in accordance with some embodiments of the present invention. For example, dimethyl propyl phosphonate (i.e., a conventional phosphorous-based flame retardant) may be functionalized to contain a vinyl functional group using procedures well known to those skilled in the art to prepare dimethyl allylphosphonate (i.e., a suitable functionalized phosphorous-based monomer).

Silica and other inorganic particles are easily functionalized via a suitable functional group-terminated silane coupling agent. For example, a conventional vinyl-terminated silane coupling agent, such as vinyltriethoxysilane, may be reacted with silica particles using procedures well known to those skilled in the art to prepare vinyl functionalized silica particles. This example corresponds to the first step in reaction scheme 1, below.

Silica and other inorganic particles are also easily hydrosilated via a suitable hydrogen-terminated silane coupling agent. For example, a conventional hydrogen-terminated silane coupling agent, such as triethoxysilane, may be reacted with silica particles using procedures well known to those skilled in the art to prepare hydrosilated terminated silica particles. This example corresponds to the first step in reaction scheme 2, below.

Typically, a coupling agent is used to join two disparate surfaces. In the manufacture of printed circuit boards (PCBs), a silane coupling agent is often used to join a varnish coating (e.g., an epoxy-based resin) to a substrate (e.g., glass cloth) to define a laminate, or laminated structure. The silane coupling agent typically consists of an organofunctional group to bind to the varnish coating and a hydrolyzable group that binds to the surface of the substrate. In particular, the alkoxy groups on the silicon hydrolyze to silanols, either through the addition of water or from residual water on the surface of the substrate. Subsequently, the silanols react with hydroxyl groups on the surface of the substrate to form a siloxane bond (Si—O—Si) and eliminate water.

A reaction scheme (reaction scheme 1) follows for synthesizing phosphorous-modified inorganic particles through an intermediate synthesis of vinyl functionalized inorganic particles in accordance with some embodiments of the present invention. Hence, reaction scheme 1 has two steps. In reaction scheme 1, inorganic particles (e.g., silicon particles) are denoted as “IP”. In the first step of reaction scheme 1, vinyl functionalized inorganic particles are produced by reacting inorganic particles and vinyltriethoxysilane. Vinyltriethoxysilane is a commercially available, conventional vinyl-terminated silane coupling agent. In the second step of reaction scheme 1, phosphorous-modified inorganic particles are produced by olefin metathesis catalyzed coupling a vinyl-terminated phosphorous-based monomer (e.g., dimethyl allylphosphonate and/or diethyl allylphosphonate) onto the vinyl functionalized inorganic particles produced in the first step. Dimethyl allylphosphonate and diethyl allylphosphonate are commercially available, bifunctional allyl phosphates.

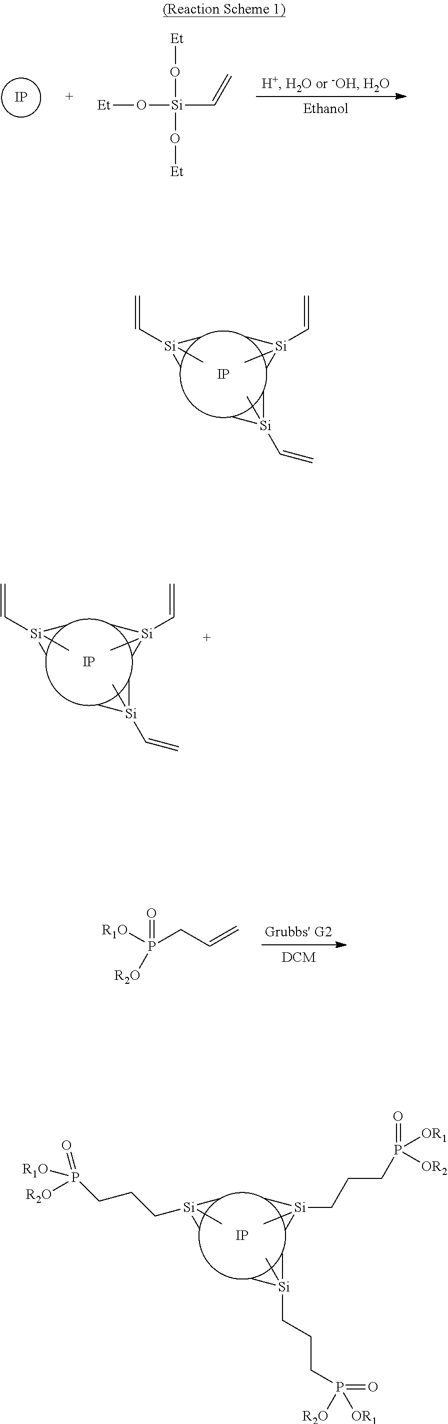

Only three silane coupling agent reaction sites are illustrated in the first step of the above reaction scheme 1 for the sake of clarity. Each silane coupling agent reaction site includes a silicon atom that attaches onto the inorganic particle, typically via three bonds each formed at an available hydroxyl group on the surface of the inorganic particle. While only three silane coupling agent reaction sites are illustrated in the first step of the above reaction scheme 1, it is typically desirable to maximize the P content of the phosphorous-modified inorganic particles (produced in the second step of the above reaction scheme 1) by reacting a quantity of the silane coupling agent sufficient to react with all of the available hydroxyl groups on the surface of the inorganic particles in the first step of the above reaction scheme 1. Hence, it is typically desirable to determine the number of available hydroxyl groups on the surface of the inorganic particles and then, in turn, determine a quantity of silane coupling agent sufficient to react with all of those available hydroxyl groups. Generally, stoichiometric quantities of the reactants may be used in the first step of the above reaction scheme 1 (i.e., one silicon atom/three available hydroxyl groups). However, the relative quantity of the reactants may be adjusted in the first step of the above reaction scheme 1 to achieve a desired level of P content of the phosphorous-modified inorganic particles (produced in the second step of the above reaction scheme 1).

The first step of the above reaction scheme 1 is performed at room temperature using conventional procedures well known to those skilled in the art. The reaction conditions may be either acidic or basic. For example, the reaction may be performed in an acid bath having a pH of approximately 4.5. Either HCl or acetic acid, for example, may be used to drop the pH to 4.5 or lower. Alternatively, the reaction may be performed in a bath having a basic pH (that is, above the isoelectric point of silica of 4.5). In this case a pH of 7-12 is preferred, most preferred is pH=10. Either ammonium or sodium hydroxide, for example, may be used to raise the pH to 7 or higher. In either case, the reaction is typically performed in the presence of ethanol (or methanol) and water. Typically, methanol is preferred for trimethoxy silanes, while ethanol is preferred for triethoxy silanes.

Only three coupling reactions are illustrated in the second step of the above reaction scheme 1 for the sake of clarity. However, it is typically desirable to maximize the P content of the phosphorous-modified inorganic particles produced in the second step of the above reaction scheme 1 by reacting a quantity of the vinyl-terminated phosphorous-based monomer sufficient to react with all of the available vinyl groups of the vinyl functionalized inorganic particles produced in the first step of the above reaction scheme 1. Generally, stoichiometric quantities of the reactants may be used. However, the relative quantity of the reactants may be adjusted to achieve a desired level of P content of the phosphorous-modified inorganic particles. The second step of the above reaction scheme 1 is performed at room temperature using conventional procedures well known to those skilled in the art. The reaction is performed in the presence of an olefin metathesis catalyst such as Grubbs' catalyst (first generation (G1) and/or second generation (G2)), Schrock akylidenes, or other catalysts known to those skilled in the art within a suitable solvent such as dichloromethane (DCM) or other solvent known to those skilled in the art to disperse the silica nanoparticles, for example, and dissolve the olefin catalyst.

A reaction scheme (reaction scheme 2) follows for synthesizing phosphorous-modified inorganic particles through an intermediate synthesis of hydrosilated terminated inorganic particles in accordance with some embodiments of the present invention. Hence, reaction scheme 2 has two steps. In reaction scheme 2, inorganic particles (e.g., silica particles) are denoted as “IP”. In the first step of reaction scheme 2, hydrosilated terminated inorganic particles are produced by reacting inorganic particles and triethoxysilane. Triethoxysilane is a commercially available, conventional hydrogen-terminated silane coupling agent. In the second step of reaction scheme 2, phosphorous-modified inorganic particles are produced by hydrosilylation catalyzed coupling of a vinyl-terminated phosphorous-based monomer (e.g., dimethyl allylphosphonate and/or diethyl allylphosphonate) onto the hydrosilated terminated inorganic particles produced in the first step. Dimethyl allylphosphonate and diethyl allylphosphonate are commercially available, bifunctional allyl phosphates.

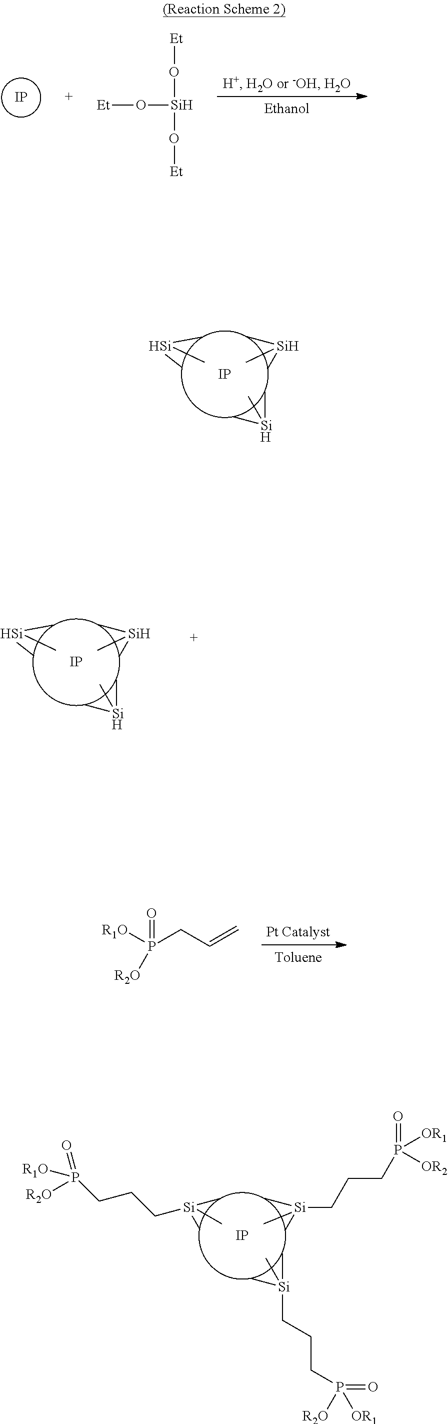

Only three silane coupling agent reaction sites are illustrated in the first step of the above reaction scheme 2 for the sake of clarity. Each silane coupling agent reaction site includes a silicon atom that attaches onto the inorganic particle, typically via three bonds each formed at an available hydroxyl group on the surface of the inorganic particle. While only three silane coupling agent reaction sites are illustrated in the first step of the above reaction scheme 2, it is typically desirable to maximize the P content of the phosphorous-modified inorganic particles (produced in the second step of the above reaction scheme 2) by reacting a quantity of the silane coupling agent sufficient to react with all of the available hydroxyl groups on the surface of the inorganic particles in the first step of the above reaction scheme 2. Hence, it is typically desirable to determine the number of available hydroxyl groups on the surface of the inorganic particles and then, in turn, determine a quantity of silane coupling agent sufficient to react with all of those available hydroxyl groups. Generally, stoichiometric quantities of the reactants may be used in the first step of the above reaction scheme 2 (i.e., one silicon atom/three available hydroxyl groups). However, the relative quantity of the reactants may be adjusted in the first step of the above reaction scheme 2 to achieve a desired level of P content of the phosphorous-modified inorganic particles (produced in the second step of the above reaction scheme 2).

The first step of the above reaction scheme 2 is performed at room temperature using conventional procedures well known to those skilled in the art. The reaction conditions may be either acidic or basic. For example, the reaction may be performed in an acid bath having a pH of approximately 4.5. Either HCl or acetic acid, for example, may be used to drop the pH to 4.5 or lower. Alternatively, the reaction may be performed in a bath having a basic pH (that is, above the isoelectric point of silica of 4.5). In this case a pH of 7-12 is preferred, most preferred is pH=10. Either ammonium or sodium hydroxide, for example, may be used to raise the pH to 7 or higher. In either case, the reaction is typically performed in the presence of ethanol (or methanol) and water. Typically, methanol is preferred for trimethoxy silanes, while ethanol is preferred for triethoxy silanes.

Only three coupling reactions are illustrated in the second step of the above reaction scheme 2 for the sake of clarity. However, it is typically desirable to maximize the P content of the phosphorous-modified inorganic particles produced in the second step of the above reaction scheme 2 by reacting a quantity of the vinyl-terminated phosphorous-based monomer to react with all of the available hydrosilated groups of the hydrosilated terminated inorganic particles produced in the first step of the above reaction scheme 2. Generally, stoichiometric quantities of the reactants may be used. However, the relative quantity of the reactants may be adjusted to achieve a desired level of P content of the phosphorous-modified inorganic particles. The second step of the above reaction scheme 2 is performed at room temperature using conventional procedures well known to those skilled in the art. The reaction is performed in the presence of a hydrosilylation catalyst such as Karstedt's catalyst (Platinum(0)-1,3-divinyl-1,1,3,3-tetramethyldisiloxane complex solution) or other catalyst known to those skilled in the art within a suitable solvent such as toluene or other solvent known to those skilled in the art to disperse the silica nanoparticles, for example, and dissolve the hydrosilylation catalyst.

The hydrosilylation catalyst used in the second step of the above reaction scheme 2 is typically a Pt catalyst. The preferred Pt catalyst is Karstedt's catalyst. However, one skilled in the art will appreciate that any of a number of other catalysts may be used. For example, [Cp*Ru(MeCN)₃]PF₆ (available from Sigma-Aldrich, St. Louis, Mo.) is a hydrosilylation catalyst that may be utilized in the second step of the above reaction scheme 2. Using [Cp*Ru(MeCN)₃]PF₆ catalyst, 2-5 mol % catalyst is typically used in acetone at room temperature.

FIG. 1 is a block diagram illustrating an exemplary printed circuit board (PCB) 100 having layers of dielectric material that incorporate a non-halogenated flame retardant filler in accordance with some embodiments of the present invention. In the embodiment illustrated in FIG. 1, the PCB 100 includes one or more module sites 105 and one or more connector sites 110. FIG. 2 is a block diagram illustrating an exemplary laminate stack-up of the PCB 100 shown in FIG. 1. The configuration of the PCB 100 shown in FIG. 1 and its laminate stack-up shown in FIG. 2 are for purposes of illustration and not limitation.

As illustrated in FIG. 2, the laminate stack-up of the PCB 100 includes conductive planes (e.g., voltage planes 205 and signal planes 210) separated from each other by dielectric material 215. For example, the voltage planes 205 include power planes P3, P5, P7, etc., while the signal planes 210 include signal planes S1, S2, S4, etc. In accordance to some embodiments of the present invention, one or more of the layers of the dielectric material 215 includes a non-halogenated flame retardant filler having phosphorous-modified inorganic particles that imparts flame retardancy.

Each layer of dielectric material (e.g., the dielectric material 215) of a PCB typically includes a varnish coating (e.g., an FR4 epoxy resin, a bismaleimide triazine (BT) resin, or a polyphenylene oxide/trially-isocyanurate (PPO/TAIC) interpenetrating network) applied to a glass fiber substrate (e.g., woven glass fiber) having its surface modified by a silane coupling agent (e.g., typically consists of an organofunctional group to bind to the varnish coating and a hydrolyzable group that binds to the surface of the glass fiber substrate, such as vinylbenzylaminoethylaminopropyl-trimethoxysilane or diallylpropylisocyanurate-trimethoxysilane). In accordance with some embodiments of the present invention, a non-halogenated flame retardant filler comprised of phosphorous-modified silica particles, for example, is incorporated into the varnish coating to impart flame retardancy.

FIG. 3 is a block diagram illustrating an exemplary connector 300 having a plastic housing 305 that incorporate a non-halogenated flame retardant filler in accordance with some embodiments of the present invention. In the embodiment illustrated in FIG. 3, the connector 300 in configured to make electrical contact with the connector site 110 (shown in FIG. 1) of the PCB 100. Also in the embodiment illustrated in FIG. 3, the connector 300 includes a cable 310. The configuration of the connector 300 shown in FIG. 3 is for purposes of illustration and not limitation.

In accordance with some embodiments of the present invention, a non-halogenated flame retardant filler comprised of phosphorous-modified silica particles, for example, is incorporated into the plastic housing 305 to impart flame retardancy. The base material of the plastic housing 305 may be, for example, liquid crystal polymer (LCP) or any suitable thermoplastic or thermoset to which the filler is added.

One skilled in the art will appreciate that many variations are possible within the scope of the present invention. Thus, while the present invention has been particularly shown and described with reference to preferred embodiments thereof, it will be understood by those skilled in the art that these and other changes in form and details may be made therein without departing from the spirit and scope of the present invention.

What is claimed is:

1. An electronic circuit board, comprising:
a laminate stack-up that includes a plurality of conductive planes separated from each other by a dielectric material, wherein the dielectric material includes a non-halogenated flame retardant filler having phosphorous-modified inorganic particles.

2. The electronic circuit board as recited in claim 1, wherein the phosphorous-modified inorganic particles include phosphorous-modified silica particles.

3. The electronic circuit board as recited in claim 1, wherein the phosphorous-modified inorganic particles include particles represented by the following formula: 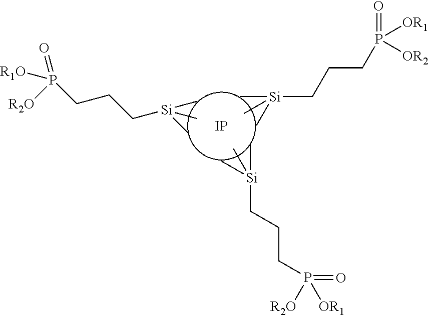
wherein IP is an inorganic particle, and wherein R₁ and R₂ are organic substituents.

4. A flame retardant filler, comprising:
non-halogenated inorganic particles, wherein the non-halogenated inorganic particles include phosphorous-modified inorganic particles.

5. The flame retardant filler as recited in claim 4, wherein the phosphorous-modified inorganic particles include phosphorous-modified silica particles.

6. The flame retardant filler as recited in claim 4, wherein the phosphorous-modified inorganic particles include particles represented by the following formula: 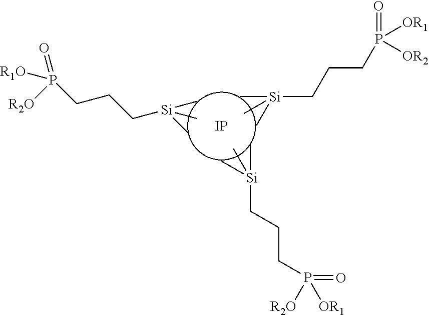
wherein IP is an inorganic particle, and wherein R₁ and R₂ are organic substituents.

7. A method of making a non-halogenated flame retardant filler, comprising the steps of:
providing modified inorganic particles selected from a group consisting of functionalized inorganic particles, hydrosilated terminated inorganic particles, and combinations thereof;
reacting the modified inorganic particles with a functionalized phosphorous-based monomer.

8. The method of making a non-halogenated flame retardant filler as recited in claim 7, wherein the modified inorganic particles comprise vinyl functionalized inorganic particles.

9. The method of making a non-halogenated flame retardant filler as recited in claim 7, wherein the modified inorganic particles comprise vinyl functionalized silica particles.

10. The method of making flame retardant filler as recited in claim 7, wherein the step of providing modified inorganic particles includes the step of functionalizing silica particles via a silane coupling agent.

11. The method of making a non-halogenated flame retardant filler as recited in claim 7, wherein the modified inorganic particles comprise hydrosilated terminated inorganic particles.

12. The method of making a non-halogenated flame retardant filler as recited in claim 7, wherein the modified inorganic particles comprise hydrosilated terminated silica particles.

13. The method of making a non-halogenated flame retardant filler as recited in claim 7, wherein the step of providing modified inorganic particles includes the step of reacting inorganic particles with a vinyl-terminated silane coupling agent, and wherein the step of reacting the modified inorganic particles with a functionalized phosphorous-based monomer includes the step of reacting the modified inorganic particles with at least one of dimethyl allylphosphonate and diethyl allylphosphonate.

14. The method of making a non-halogenated flame retardant filler as recited in claim 13, wherein the inorganic particles are silica particles and wherein the vinyl-terminated silane coupling agent is vinyltriethoxysilane.

15. The method of making a non-halogenated flame retardant filler as recited in claim 7, wherein the step of reacting the modified inorganic particles with a functionalized phosphorous-based monomer produces phosphorous-modified inorganic particles represented by the following formula: 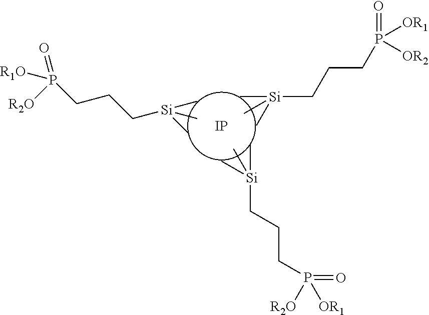
wherein IP is an inorganic particle, and wherein R₁ and R₂ are organic substituents.

16. An article of manufacture, comprising:
a housing comprising a plastic material, wherein the plastic material includes a non-halogenated flame retardant filler having phosphorous-modified inorganic particles.

17. The article of manufacture as recited in claim 16, wherein the phosphorous-modified inorganic particles include phosphorous-modified silica particles.

18. The flame retardant filler as recited in claim 16, wherein the phosphorous-modified inorganic particles include particles represented by the following formula: 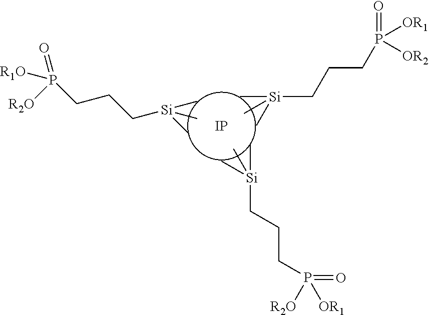
wherein IP is an inorganic particle, and wherein R₁ and R₂ are organic substituents.

19. The article of manufacture as recited in claim 16, wherein the article of manufacture is a connector.
